(19) United States
(12) Patent Application Publication
(10) Pub. No.: US 2004/0104755 A1
(43) Pub. Date: Jun. 3, 2004

(54) SDI signal discriminating apparatus

(76) Inventor: Noriyuki Suzuki, Kanagawa (JP)

Correspondence Address: FISH & RICHARDSON P.C., 1425 K STREET, N.W., 11TH FLOOR, WASHINGTON, DC, 20005-3500, US

(21) Appl. No.: 10/353,973

(22) Filed: Jan. 30, 2003

(30) Foreign Application Priority Data
Jan. 31, 2002 (JP) 23571/2002

(51) Int. Cl. H03K 3/00; G06F 1/04

(52) U.S. Cl. 327/300; 375/373

(57) ABSTRACT

An SDI signal discriminating apparatus for discriminating the type of an SDI signal. The SDI signal type discriminating apparatus comprises an HD-SDI type detector which generates an HD lock signal HD_LOCK when it detects a first periodic component included in an HD-SDI signal in the received SDI signal, and an SD-SDI type detector which generates an SD lock signal SD_LOCK when it detects a second periodic component included in an SD-SDI signal in the received SDI signal. The first periodic component differs in period from the second periodic component.

### BACKGROUND OF THE INVENTION

The present invention relates to a method and apparatus for discriminating different types of serial digital interface (SDI) signals.

SDI signals can be classified into two types: a high definition SDI (HD-SDI) signal and a standard SDI (SD-SDI) signal. While a HD-SDI signal has a bit rate of 1.485 Gb/s, a SD-SDI signal has a different bit rate, i.e., 270 Mb/s. Therefore, in conventional devices such as circuits or measuring devices for processing SDI signals, two circuits are typically provided for an HD-SDI signal and SD-SDI signal, respectively. However, by using this-method, costs are increased since it is necessary to provide similar circuits for processing SDI signals in these devices.

### SUMMARY OF THE INVENTION

It is therefore an object of the present invention to overcome the foregoing problem, and more specifically, to provide a method and apparatus for discriminating a type of SDI signal.

It is another object of the present invention to provide an integrated circuit or a device which comprises a discriminating apparatus.

To achieve the stated object, an SDI signal discriminating method according to the present invention discriminates a type of received SDI signal. The method includes a first detecting step of detecting in the received SDI signal a first periodic component included in a first type of SDI signal to generate a first type detection signal indicating detection of the first type of SDI signal, and a second detecting step of detecting in the received SDI signal a second periodic component included in a second type of SDI signal to generate a second type detection signal indicating detection of the second type of SDI signal, wherein the second periodic component is different in period from the first periodic component.

According to the present invention, the first detecting step can generate the first type detection signal when the first periodic component is detected for at least a first predetermined period of time, and the second detecting step can generate the second type detection signal when the second periodic component is detected for at least a second predetermined period of time.

Also, an SDI signal discriminating apparatus according to the present invention discriminates a type of an SDI signal. The apparatus includes first detecting means connected to receive an SDI signal for generating a first type detection signal when the first detecting means detects a first periodic component included in a first type of SDI signal, and second detecting means connected to receive the SDI signal for generating a second type detection signal when the second detecting means detects a second periodic component included in a second type of SDI signal, wherein the second periodic component is different in period from the first periodic component.

According to the present invention, the first detecting means can generate the first type detection signal when the first periodic component is detected for at least a first predetermined period of time, and the second detecting means can generate the second type detection signal when the second periodic component is detected for at least a second predetermined period of time. Each of the first and second detecting means can comprise a PLL.

Also, according to the present invention, the first detecting means may further include first stable state determining means for generating the first type detection signal when a signal indicative of a locked state of the PLL in the first detecting means continues for the at least first predetermined period of time, and the second detecting means may further include second stable state determining means for generating the second type detection signal when a signal indicative of a locked state of the PLL in the second detecting means continues for the at least second predetermined period of time.

Further, according to the present invention, the first type of SDI signal can be a standard SDI (SD-SDI) signal, and the second type of SDI signal can be a high definition SDI (HD-SDI) signal.

The present invention also provides a device which includes the foregoing SDI signal discriminating apparatus. According to the present invention, the device can be a measuring device or a video device.

The present invention further provides an integrated circuit comprising the foregoing SDI signal discriminating apparatus.

The present invention further provides an SDI signal processing apparatus for processing an SDI signal input. The SDI signal processing apparatus includes the aforementioned SDI signal discriminating apparatus, and processing means responsive to the first type detection signal or the second type detection signal from the discriminating apparatus for processing the SDI signal input as the first or second type of SDI signal.

The present invention further provides a device which includes the aforementioned signal processing apparatus. According to the present invention, the device can be a measuring device or a video device.

The present invention further provides an integrated circuit which includes the aforementioned signal processing apparatus.

In the following, embodiments of the present invention will be described with reference to the accompanying drawings.

### BRIEF DESCRIPTION OF THE INVENTION

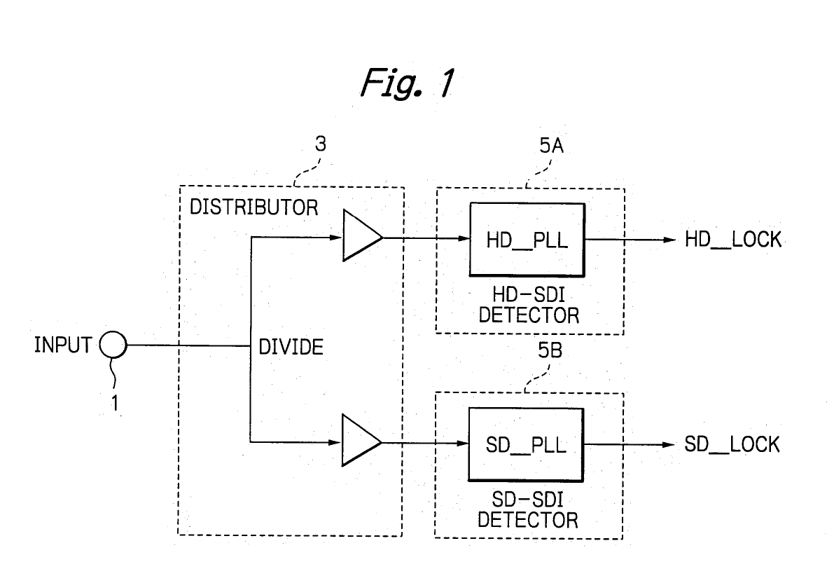

FIG. 1 is a block diagram illustrating an SDI signal type discriminating apparatus according to the present invention;

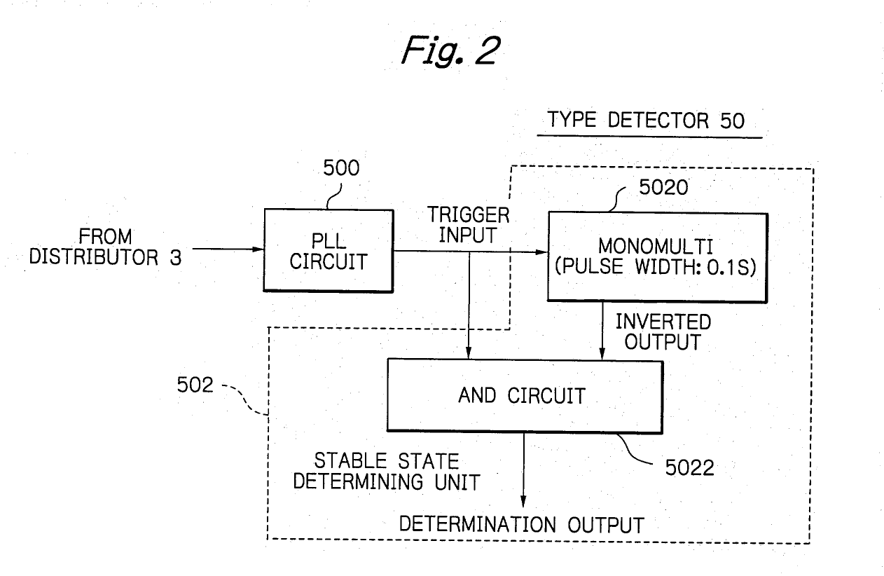

FIG. 2 is a block diagram illustrating another embodiment of a type detector in FIG. 1; and

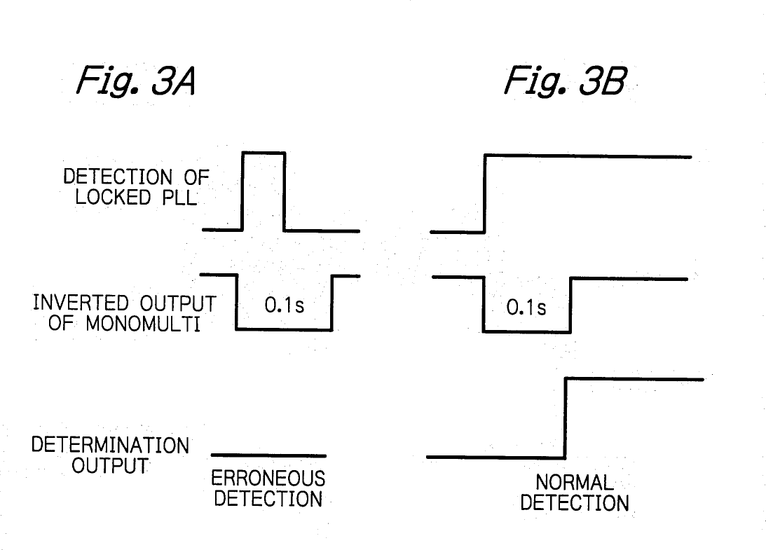

FIGS. 3A and 3B are timing diagrams showing the operation of the type detector in FIG. 2.

### DETAILED DESCRIPTION OF THE INVENTION

FIG. 1 illustrates a block diagram of an SDI signal type discriminating apparatus according to the present invention. As illustrated, the discriminating apparatus comprises an input terminal 1 for receiving an SDI signal; a distributor 3; an HD-SDI type detector 5A; and an SD-SDI type detector 5B. More specifically, the input terminal 1 receives an SDI signal which can be one of two types as described above: an HD-SDI signal and an SD-SDI signal. The HD-SDI signal has a bit rate of 1.485 Gb/s, while the SD-SDI signal has a bit rate of 270 Mb/s. However, the bit rates of these signals are a maximum bit rate, and therefore an SDI signal may be at a bit rate lower than that maximum bit rate depending on a signal content. The distributor 3 has an input for receiving the SDI signal from the input terminal 1. After impedance matching and required amplification or attenuation, the distributor 3 generates the resulting SDI signal at two outputs. The HD-SDI type detector 5A has an input for receiving the SDI signal from the distributor 3, and an output for generating a detection signal indicative of a detected HD-SDI signal when it detects the HD-SDI signal. Similarly, the SD-SDI type detector 5B has an input for receiving the SDI signal from the distributor 3, and an output for generating a detection signal indicative of a detected SD-SDI signal when it detects the SD-SDI signal.

In one embodiment of the present invention, each of the detectors 5A, 5B comprises a phase lock loop (PLL), i.e., an HD_PLL or an SD_PLL, as illustrated in FIG. 1. These PLLs are designed to be locked to the respective maximum bit rates. Here, an SDI signal includes a mixture of a periodic component at the maximum bit rate and periodic components each at a bit rate which is an integral submultiple of the maximum bit rate. However, the edge of the SDI signal, at which the PLL compares the phase, is at the same position on the waveform (for example, a rising edge) irrespective of the bit rate, so that the PLL can be momentarily locked to a different periodic component. The PLL, nevertheless, is generally locked to the periodic component at the maximum rate in continuation, due to a fly wheel effect of the PLL itself, to generate a lock signal HD_LOCK or SD_LOCK. A PLL lock range is defined to be as narrow as possible in consideration of system requirements such as absorption of jitter of the SDI signal. In an example, the lock range may be approximately from 1 to 15% of the center frequency (maximum bit rate) of a VCO which forms part of the PLL.

Next, describing the operation of the discriminating apparatus in FIG. 1, when the SDI signal received at the input terminal 1 is an HD-SDI signal, the HD-SDI signal is supplied to the HD-SDI type detector 5A and SD-SDI type detector 5B. Since this is an HD-SDI signal, the HD-SDI type detector 5A alone generates the detection signal, i.e., the lock signal HD_LOCK. In this way, the HD-SDI type detector 5A indicates that the received SDI signal is an HD-SDI signal. The other SD-SDI type detector 5B does not generate a detection signal. On the other hand, when the received SDI signal is an SD-SDI signal, the SD-SDI type detector 5B alone generates the detection signal, i.e., the lock signal SD_LOCK, thereby indicating that the received SDI signal is an SD-SDI signal. In this way, SDI signals can be simply discriminated.

Next, FIG. 2 illustrates another embodiment of the HD-SDI type detector 5A and SD-SDI type detector 5B. This embodiment is particularly effective when a common periodic component is included in periodic components of both of an HD-SDI signal and an SD-SDI signal. Specifically, the HD-SDI signals are classified into two systems which differ in transmission bit rate, i.e., a 1.485 GHz system and a 1.485 GHz/1.001 system. While the former 1.485 GHz system implies a multiple relationship with an SD system, the latter system is free from any such multiple relationship. In other words, in the former 1.485 GHz system, the bit rates of the HD-SDI and SD-SDI are in a ratio of 11:2, so that dividing the maximum bit rate of each system by its ratio results in the same value: (1.485 Gb/s)/11=135 Mb/s or (270 Mb/s)/2=135 Mb/s. Thus, a periodic component at 135 Mb/s is a common component in the HD-SDI signal and SD-SDI signal. Upon receipt of this periodic component, the respective PLLs are both locked. However, because of a low probability that this periodic component will be continuous, even if both PLLs are momentarily locked, erroneous detection can be prevented by checking whether or not the locked state remains stable over a certain period of time. The embodiment illustrated in FIG. 2 is provided to prevent such erroneous detection.

Specifically, the type detector 50 illustrated in FIG. 2 can be used in either the detector 5A or the detector 5B. More specifically, the type detector 50 comprises a PLL circuit 500 identical to the PLL shown in FIG. 1, and a stable state determining unit 502. The stable state determining unit 502 comprises a mono-multivibrator 5020 and an AND gate circuit 5022. The PLL circuit 500 has an input for receiving an SDI signal from the distributor 3 in FIG. 1, and an output for generating a lock signal such as an HD_PLL signal or an SD_PLL signal when it is locked. The mono-multi 5020 has a trigger input connected to the output of the PLL circuit 500, and has a function of generating, when it is triggered, a high pulse for a predetermined period of time (for example, 0.1 second) after a triggered time and generating an inverted output at its output. The AND gate circuit 5022 has one input connected to the output of the PLL circuit 500, another input connected to an inverted output of the mono-multi 5020, and an output at which the AND gate circuit 5022 generates the result of a logical AND operation performed on the two inputs. This output is the detection signal (or a determination output) described in FIG. 1.

Next, the operation of the circuit in FIG. 2 will be described with reference to FIGS. 3A and 3B. As illustrated in FIG. 3A, when the PLL is momentarily locked to generate a lock signal for a period of time shorter than 0.1 second, the mono-multi 5020 is triggered by the lock signal to generate an output at low for 0.1 second. The AND gate circuit 5022 receives the lock signal and the inverted output of the mono-multi 5020. The output of the mono-multi 5020 is at low while the lock signal remains at high, and the output of the mono-multi 5020 still remains at low when the lock signal changes to low. Therefore, the output of the AND gate circuit 5022 remains at low, so that the AND gate circuit 5022 does not generate a signal indicative of a detected HD-SDI or SD-SDI signal. On the other hand, as illustrated in FIG. 3B, when the PLL is continuously locked for a period of time longer than 0.1 second, the output of the mono-multi 5020 returns to high 0.1 second after the time it was triggered. Thus, the output of the AND gate circuit 5022 goes high when the output of the mono-multi 5020 returns to high, resulting in the generation of the detection signal indicative of a detected HD-SDI or SD-SDI signal. In the HD_PLL circuit and SD_PLL circuit, the period of time associated with the mono-multi 5020, such as 0.1 second, may be set to the same value or a different value. In this way, the stable state determining unit 502 can prevent an erroneous detection which could be caused by a periodic component common to the HD-SDI signal and SD-SDI signal.

While the foregoing embodiment of the present invention shows an exemplary set time of 0.1 second for the mono-multi 5020, those skilled in the art can modify the set time to another value found from experiment or the like, as required, with the aim of preventing erroneous detection. The discriminating apparatus can be incorporated in a video device, any other device including a video measuring device which handles SDI signals, or an integrated circuit.

As described above in detail, by using the SDI signal discrimination according to the present invention it becomes possible to simplify a common part in two circuits in a device, or a circuit which handles an SDI signal, thereby making it possible to realise a significant reduction in costs. In addition, use of the stable state determining unit makes it possible to prevent erroneous detection of the SDI signal, and accordingly to detect the SDI signal in a stable manner.

What is claimed is:

1. An SDI signal discriminating method for discriminating a type of a received SDI signal, comprising:
a first detecting step of detecting in the received SDI signal a first periodic component included in a first type of SDI signal to generate a first type detection signal indicating detection of the first type of SDI signal; and
a second detecting step of detecting in the received SDI signal a second periodic component included in a second type of SDI signal to generate a second type detection signal indicating detection of the second type of SDI signal, said second periodic component being different in period from said first periodic component.

2. An SDI signal discriminating method according to claim 1, wherein:
said first detecting step includes generating the first type detection signal when the first periodic component is detected for at least a first predetermined period of time; and
said second detecting step includes generating the second type detection signal when the second periodic component is detected for at least a second predetermined period of time.

3. An SDI signal discriminating apparatus for discriminating a type of an SDI signal, comprising:
first detecting means connected to receive an SDI signal for generating a first type detection signal when said first detecting means detects a first periodic component included in a first type of SDI signal; and
second detecting means connected to receive the SDI signal for generating a second type detection signal when said second detecting means detects a second periodic component included in a second type of SDI signal, said second periodic component being different in period from said first periodic component.

4. An SDI signal discriminating apparatus according to claim 3, wherein
said first detecting means generates the first type detection signal when the first periodic component is detected for at least a first predetermined period of time; and
said second detecting means generates the second type detection signal when the second periodic component is detected for at least a second predetermined period of time.

5. An SDI signal discriminating apparatus according to claim 4, wherein each of said first and second detecting means comprises a PLL.

6. An SDI signal discriminating apparatus according to claim 5, wherein:
said first detecting means further includes first stable state determining means for generating the first type detection signal when a signal indicative of a locked state of said PLL in said first detecting means continues for said at least first predetermined period of time; and
said second detecting means further includes second stable state determining means for generating the second type detection signal when a signal indicative of a locked state of said PLL in said second detecting means continues for said at least second predetermined period of time.

7. An SDI signal discriminating apparatus according to any of claims 3 to 6, wherein:
said first type of SDI signal is a standard SDI (SD-SDI) signal, and said second type of SDI signal is a high definition SDI (HD-SDI) signal.

8. A device comprising an SDI signal discriminating apparatus according to any of claims 3 to 7.

9. A device according to claim 8, wherein said device is a measuring device.

10. A device according to claim 8, wherein said device is a video device.

11. An integrated circuit comprising an SDI signal discriminating apparatus according to any of claims 3 to 7.

12. An SDI signal processing apparatus for processing an SDI signal input, comprising:
an SDI signal discriminating apparatus according to any of claims 3 to 7; and
processing means responsive to the first type detection signal or the second type detection signal from said discriminating apparatus for processing said SDI signal input as the first or second type of SDI signal.

13. A device comprising the signal processing apparatus according to claim 12.

14. A device according to claim 13, wherein said device is a measuring device.

15. A device according to claim 13, wherein said device is a video device.

16. An integrated circuit comprising the signal processing apparatus according to claim 12.
